(19) United States
(12) Patent Application Publication
(10) Pub. No.: US 2010/0246149 A1
(43) Pub. Date: Sep. 30, 2010

(54) CONNECTION MEMBER AND PRINTED CIRCUIT BOARD UNIT

(75) Inventors: Tomokazu Nakashima, Kawasaki (JP); Kiyokazu Moriizumi, Kawasaki (JP); Masayuki Itoh, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/718,348

(22) Filed: Mar. 5, 2010

(30) Foreign Application Priority Data
Mar. 30, 2009 (JP) 2009-81761

(51) Int. Cl. H05K 7/02; H01R 12/02

(52) U.S. Cl. 361/767; 174/262; 361/783

(57) ABSTRACT

A connection member is disposed between a semiconductor package and a printed wiring board. The connection member includes: a base member formed of an insulating material; a plurality of through-holes provided in the base member at corresponding positions between a plurality of first terminal pads of the semiconductor package and a plurality of second terminal pads of the printed wiring board; and an electronic component inserted in the plurality of through-holes, the electronic component having a first electrode and a second electrode at ends thereof, the first electrode connected to one of the first terminal pads, the second electrode connected to one of the second terminal pads.

### CROSS-REFERENCE TO RELATED APPLICATION

This application is based upon and claims the benefit of priority of the prior Japanese Patent Application No. 2009-81761, filed on Mar. 30, 2009, the entire contents of which are incorporated herein by reference.

### FIELD

The embodiments discussed herein are related to a connection member that is disposed, for example, between a semiconductor package and a printed wiring board.

### BACKGROUND

A printed circuit board unit is incorporated into, for example, a server computer apparatus. The printed circuit board unit typically includes a large scale integrated circuit (LSI) chip package that is implemented on the front surface of a printed wiring board. A package substrate of the LSI chip package is implemented on the printed wiring board, for example, using a ball grid array (BGA) or a land grid array (LGA). Chip-type electronic components, such as registers, capacitors, or inductors, are implemented as peripheral circuit components for the LSI chip package on the front or rear surface of the printed wiring board. The chip-type electronic components are electrically connected via the printed wiring board to an LSI chip that is implemented on the front surface of the package substrate.

In the related art, a package substrate of an LSI chip package is joined, using a connection member, onto a printed wiring board. The connection member includes an insulating base member. The base member includes through-holes that are provided at positions corresponding to terminal pads on the package substrate and terminal pads on the printed wiring board. The through-holes are filled with solder members.

When the connection member structured as mentioned above is sandwiched between the package substrate and the printed wiring board, the terminal pads on the package substrate and the terminal pads on the printed wiring board are connected to each other using the solder members. The solder members given above are used instead of the BGA (see Japanese Laid-Open Patent Publication Nos. 2003-158225 and 10-12989).

Wiring patterns or through-holes in a printed wiring board are used for connection of an LSI chip package to electronic components. Because the electronic components are disposed in the vicinity of the LSI chip package, the lengths of the wiring patterns between the LSI chip package and the electronic components are comparatively long. Additionally, the pitch of terminal pads of the LSI chip package is small. Accordingly, the widths of the wiring patterns that lead out from the terminal pads are small, and a radius of the through-holes that are disposed with a pitch which is the same as that of the terminal pads is small.

As a result, an increase in a loss R or an inductance L occurs in connection lines between the LSI chip package and the electronic components from an electrical perspective. When a current flows through the connection lines, a voltage decreases because of an increase in the loss R. For example, when the voltage of a power-supply line markedly decreases, the voltage becomes lower than the operating voltage of an LSI chip.

Accordingly, the LSI chip cannot operate. Furthermore, on a signal line, as the frequency of a square wave signal increases, i.e., as the voltage of the signal changes faster, distortion occurs in the waveform of the signal because of an increase in the inductance L, and noise on the power-supply line increases in response to change in the voltage of the signal. As a result, a probability of malfunction increases, and electronic performance of a circuit of the LSI chip is reduced.

### SUMMARY

According to an embodiment, a connection member is disposed between a semiconductor package and a printed wiring board. The connection member includes: a base member formed of an insulating material; a plurality of through-holes provided in the base member at corresponding positions between a plurality of first terminal pads of the semiconductor package and a plurality of second terminal pads of the printed wiring board; and an electronic component inserted in the plurality of through-holes, the electronic component having a first electrode and a second electrode at ends thereof, the first electrode connected to one of the first terminal pads, the second electrode connected to one of the second terminal pads.

It is to be understood that both the foregoing general description and the following detailed description are exemplary, and do not restrict the invention as claimed.

### BRIEF DESCRIPTION OF DRAWINGS

The above and other features and advantages of the present invention will become apparent from the following description of the embodiments in conjunction with the accompanying drawings, wherein:

FIG. 1 is a schematic perspective view of a specific example of electronic equipment, i.e., a server computer apparatus;

FIG. 2 is a schematic perspective view of a structure of a printed circuit board unit according to a first embodiment of the present invention;

FIG. 3 is a sectional view taken along the line of FIG. 2, and schematically illustrates the structure of the printed circuit board unit according to the first embodiment of the present invention;

FIG. 4 schematically illustrates a state in which electronic components and metal objects are disposed in through-holes of a base member in production of a connection member;

FIG. 5 is a schematic sectional view illustrating a state in which the connection member is sandwiched between a printed wiring board and a package substrate in production of the printed circuit board unit;

FIG. 6 is a schematic sectional view of a structure of a printed circuit board unit according to a second embodiment of the present invention, which corresponds to FIG. 3;

FIG. 7 is a schematic sectional view of a structure of a printed circuit board unit according to a third embodiment of the present invention, which corresponds to FIG. 3;

FIG. 8 is a schematic sectional view of a structure of a printed circuit board unit according to a fourth embodiment of the present invention, which corresponds to FIG. 3;

FIG. 9 is a schematic sectional view of a structure of a printed circuit board unit according to a fifth embodiment of the present invention, which corresponds to FIG. 3;

FIG. 10 is a schematic sectional view illustrating a state in which detachment-prevention films are attached to the front and rear surfaces of the base member in production of the connection member;

FIG. 11 is a schematic sectional view illustrating a state in which a connection member unit is disposed on the printed wiring board in production of the printed circuit board unit;

FIG. 12 is a schematic sectional view illustrating a state in which the connection member is sandwiched between the printed wiring board and the package substrate in the production of the printed circuit board unit;

FIG. 13 is a circuit diagram that is assumed in simulation; and

FIG. 14 is a graph illustrating a variation in voltage in a specific example and a variation in voltage in a comparison example.

### DESCRIPTION OF EMBODIMENTS

Hereinafter, embodiments of the present invention will be described with reference to the accompanying drawings.

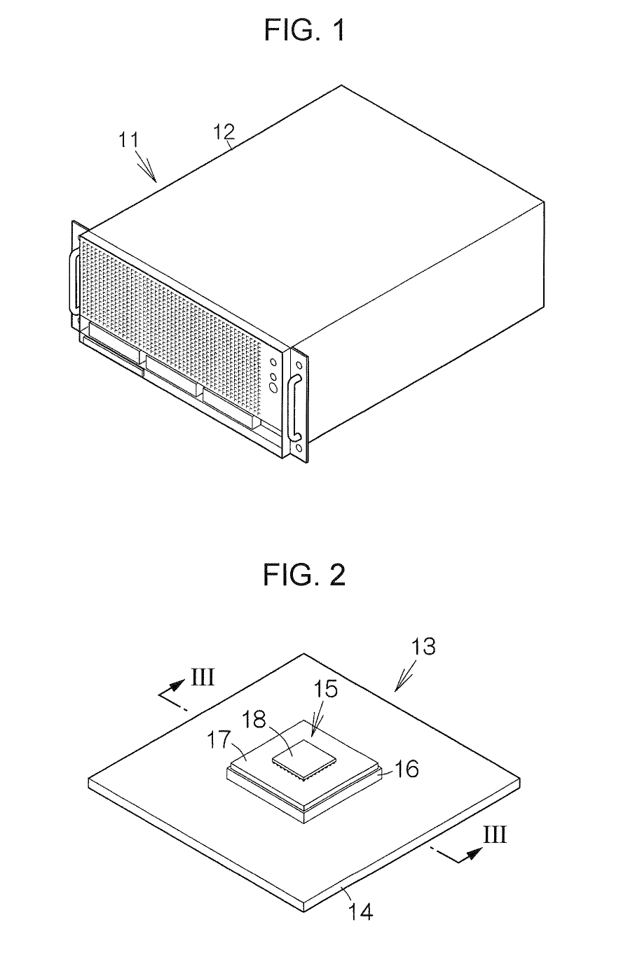

FIG. 1 schematically illustrates the external appearance of a specific example of electronic equipment, e.g., a server computer apparatus 11. The server computer apparatus 11 includes a housing 12. In the housing 12, housing spaces are provided as divided spaces. In one of the housing spaces, a printed circuit board unit is disposed. The printed circuit board unit is provided with, for example, a semiconductor component and a main memory.

The semiconductor component performs various types of arithmetic processing, for example, in accordance with a software program and data that are temporarily held in the main memory. The software program and data may be stored in a large-capacity storage device, such as a hard disk drive device (HDD), which is similarly disposed in one of the housing spaces. The server computer apparatus 11 structured as described above is mounted, for example, in a rack.

FIG. 2 schematically illustrates a structure of a printed circuit board unit 13 according to a first embodiment of the present invention. The printed circuit board unit 13 is disposed in the housing 12. The printed circuit board unit 13 includes a printed wiring board 14. For example, a resin board may be used as the printed wiring board 14. A semiconductor package, e.g., an LSI chip package 15, is implemented on the front surface of the printed wiring board 14. A connection member 16 is sandwiched between the printed wiring board 14 and the LSI chip package 15. With a function of the connection member 16, the LSI chip package 15 is implemented on the front surface of the printed wiring board 14. In this manner, the LSI chip package 15 is electrically and mechanically connected to the printed wiring board 14.

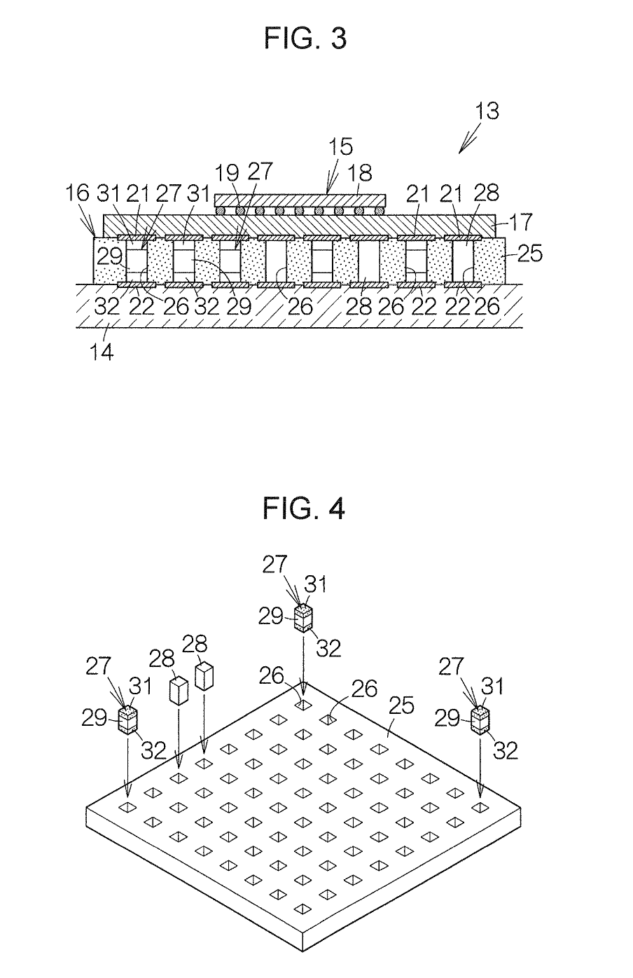

As illustrated in FIG. 3, the LSI chip package 15 includes a package substrate 17. For example, a ceramic board may be used as the package substrate 17. An LSI chip 18 is implemented on the front surface of the package substrate 17. On the front surface of the package substrate 17, terminal bumps 19 are arranged in a matrix form. The LSI chip 18 is received by the terminal bumps 19. With a function of the terminal bumps 19, the LSI chip 18 is implemented on the front surface of the package substrate 17.

Further, the LSI chip 18 may be implemented on the package substrate 17, for example, using die bonding or wire bonding. On the front surface of the package substrate 17, a heat spreader and/or a heat sink (not illustrated) may be attached on the LSI chip 18.

On the rear surface of the package substrate 17, a plurality of terminal pads 21 are arranged in a matrix form. On the other hand, on the front surface of the printed wiring board 14, a plurality of terminal pads 22 are arranged in a matrix form. The terminal pads 21 on the package substrate 17 correspond to the terminal pads 22 on the printed wiring board 14 in a one-to-one manner. Here, the terminal pads 21 and 22 may have, for example, a rectangular contour.

The front surfaces of the terminal pads 21 and the front surfaces of the terminal pads 22 are preferably flat. The front surfaces of the terminal pads 21 are preferably parallel to the front surfaces of the terminal pads 22. The terminal pads 21 and 22 may be formed of, for example, copper. Note that the shape and size of the terminal pads 21 may not coincide with those of the terminal pads 22.

However, the terminal pads 21 and 22 are designed so that the pitch of the terminal pads 21 and the pitch of the terminal pads 22 coincide with each other.

The connection member 16 includes a base member 25. The base member 25 may be formed, for example, in the shape of a flat rectangular parallelepiped. The front and rear surfaces of the base member 25 are parallel to each other. One of the front and rear surfaces of the base member 25 is configured as either a first face or a second face. The other surface is configured as the remaining face.

The base member 25 extends between the printed wiring board 14 and the package substrate 17 so that the thickness of the base member 25 is uniform. The front surface of the base member 25 receives the rear surface of the package substrate 17.

The rear surface of the base member 25 is received by the front surface of the printed wiring board 14. The base material 25 may be formed of an insulating high-polymer material. Here, the base member 25 may be formed of, for example, a thermosetting resin material or a thermoplastic resin material.

In the base member 25, a plurality of through-holes 26 are formed so that the plurality of through-holes 26 pass through from the front surface of the base member 25 to the rear surface of the base member 25. The through-holes 26 are arranged in a matrix form in correspondence with the positions of the terminal pads 21 and 22.

Here, the through-holes 26 correspond to the terminal pads 21 in a one-to-one manner. The through-holes 26 also correspond to the terminal pads 22 in a one-to-one manner. As a result, on the front surface of the base member 25, the through-holes 26 open toward the terminal pads 21. Similarly, on the rear surface of the base member 25, the through-holes 26 open toward the terminal pads 22.

In this manner, the positions of the through-holes 26 are specified in correspondence with the positions of the terminal pads 21 and 22. In the first embodiment, the through-holes 26 are provided as, for example, rectangular column-shaped spaces.

Chip-type electronic components 27 and metal objects 28 are individually disposed in the respective through-holes 26. Examples of the electronic components 27 include rectangular column-shaped chip resistors, chip capacitors, and chip inductors.

As described below, each of the electronic components 27 in the first embodiment has electrodes at the ends thereof in longitudinal directions, that is, the upper end and the lower end. The electronic component 27 and the metal object 28 are oriented vertically in the through-holes 26. The electronic component 27 and the metal object 28 are in contact with an inner wall of the through-holes 26.

In this manner, the electronic component 27 and the metal object 28 are reliably held in the through-holes 26. The electronic component 27 or the metal object 28 may be, for example, press-fitted in the through-holes 26.

Here, all of the electronic components 27 that are to be disposed in the through-holes 26 have the same end-to-end length, that is, the length from the upper end to the lower end. Each of the electronic components 27 may be configured using, for example, any one of a Japanese Industrial Standard (JIS) code 1005-size chip and a JIS code 0603-size chip. The dimensions of the electronic component 27 are specified in accordance with standards. The JIS code 1005-size chip corresponds to an Electronics Industries Alliance (EIA) standard code 0402-size chip. The JIS code 0603-size chip corresponds to an EIA standard code 0201-size chip.

For example, regarding the JIS code 1005-size chip, a length of 1.0 mm is defined as an end-to-end length. Simultaneously, a width of 0.5 mm and a thickness of 0.5 mm are defined as being in directions parallel to the front surface of the printed wiring board 14. Similarly, for example, regarding a 0603-size chip, a length of 0.6 mm, a width of 0.3 mm, and a thickness of 0.3 mm are defined.

In the first embodiment, for example, JIS code 1005-size chips are employed as the electronic components 27. Note that the thickness of the electronic components 27 may not be the same as the width thereof. The thickness of the electronic components 27 may be defined to be equal to or smaller than a thickness specified in the standards, e.g., to be 0.35 mm.

Each of the electronic components 27 includes a chip body 29 having, for example, a rectangular column shape. The chip body 29 includes a base member that is formed of, for example, a ceramic material. In the base member, for example, registers or internal electrodes are disposed. A pair of external electrodes 31 and 32 is provided at the ends, i.e., the upper end and the lower end, of the chip body 29.

The electrodes 31 and 32 are exposed at opening portions of the through-hole 26. The electrode 31 has a flat surface, and the flat surface receives a corresponding terminal pad 21. The electrode 32 has a flat surface, and the flat surface is received by a corresponding terminal pad 22. The electronic component 27 electrically connects, to the terminal pad 21, the corresponding terminal pad 22. In this manner, the electronic component 27 is connected in series with the LSI chip package 15.

The electrodes 31 and 32 may be formed of, for example, copper. On the surface of the copper, for example, a tin plating film or a nickel plating film may be formed.

Each of the metal objects 28 is formed, for example, in a rectangular column shape as in the case of the electronic component 27. Preferably, the external shape of the metal object 28 is substantially the same as that of the electronic component 27.

Similarly, the end-to-end length of the metal object 28 is set to be a length that is the same as the end-to-end length of the electronic component 27. However, the width and thickness of the metal object 28 may be different from the width and thickness of the electronic component 27. The upper end of the metal object 28 has a flat surface, and the flat surface receives a corresponding terminal pad 21.

The lower end of the metal object 28 has a flat surface, and the flat surface is received by a corresponding terminal pad 22. In this manner, the metal object 28 electrically connects, to the terminal pad 21, the corresponding terminal pad 22. The metal object 28 has a melting point which is higher than, for example, the melting point of a solder used to join a pad to a component.

The metal object 28 structured as described above is formed of, for example, a base material and a metal plating film that is formed on the surface of the base material. For example, any one of conductive metallic materials including copper, copper alloys, such as a phosphor-bronze alloy, a copper-iron alloy, and a copper-nickel alloy, iron, and alloys such as 42-alloy (an iron-42 nickel alloy), and Kovar (an iron-29 nickel-17 cobalt alloy) may be used as the base material.

On the surface of the base material, for example, a metal plating film, e.g., any one of a tin plating film, a gold plating film, a silver plating film, a palladium plating film, a tin-bismuth alloy plating film, a tin-copper alloy plating film, and a tin-silver alloy plating film, is formed. In the first embodiment, for example, pure copper is used for the base material. Copper has a melting point which is higher than, for example, the melting point of a eutectic solder, such as a tin-lead alloy, or the melting point of a high-temperature solder, such as a tin-silver-copper alloy.

In the above-described printed circuit board unit 13, the electronic components 27 are incorporated into the connection member 16. The electronic components 27 are sandwiched between the terminal pads 21 and 22. In this manner, the electronic components 27 are electrically connected to the LSI chip 18.

As a result, distances between the electronic components 27 and the LSI chip package 15 are markedly reduced, compared with distances between electronic components and the LSI chip package 15 in a case in which the electronic components are implemented outside the contour of the LSI chip package 15 on the front surface of the printed wiring board 14, or in a case in which the electronic components are implemented on the rear surface of the printed wiring board 14.

The electronic components 27 are directly connected to the LSI chip package 15, for example, without wiring patterns or through-holes. As a result, an increase in a loss R or an inductance L may be markedly reduced. In the printed circuit board unit 13, electronic performance which is higher than that in the related art may be realized.

Additionally, the chip-type electronic components, which are implemented outside the contour of the LSI chip package 15 on the front surface of the printed wiring board 14 or the rear surface of the printed wiring board 14 in the related art, are disposed inside the contour of the LSI chip package 15 between the printed wiring board 14 and the package substrate 17.

Accordingly, a space for implementation of the electronic components on the front or rear surface of the printed wiring board 14 is reduced. As a result, the area of the front or rear surface is reduced. Miniaturization of the printed wiring board 14 is realized. In addition, if the metal objects 28 are formed of, for example, pure copper, the electrical conductivity of the metal objects 28 will be higher than the electrical conductivity of a solder.

A variation in voltage in a case in which a large current flows through the metal objects 28 may be reduced. The electric performance of the printed circuit board unit 13 may be markedly improved.

Next, a method for producing the printed circuit board unit 13 will be described. First, the connection member 16 is produced. As illustrated in FIG. 4, the base member 25 is formed of, for example, a thermoplastic resin material. The base member 25 may be formed using the solid-state resin material at a room temperature.

The plurality of through-holes 26 are formed in the base member 25. The through-holes 26 are formed to have, for example, a rectangular column shape. The dimensions of the through-holes 26 are defined as being in directions parallel to the front or rear surface of the base member 25. Each of the dimensions of the through-holes 26 may be set to be slightly smaller than a corresponding dimension of the width and thickness of the electronic components 27 or a corresponding dimension of the width and thickness of the metal objects 28.

Here, each of the dimensions of the through-holes 26 is set to be smaller than 0.45 mm which may be the minimum width and minimum thickness of the electronic components 27 determined based on tolerances. The through-holes 26 structured as described above are formed, for example, using injection molding when the base member 25 is formed. The pitch of the through-holes 26 is designed so that the pitch coincides with the pitch of the terminal pads 21 and the pitch the terminal pads 22.

Next, the electronic components 27 or the metal objects 28 are inserted into the through-holes 26, for example, from the front surface of the base member 25 while the electronic components 27 or the metal objects 28 in a vertical orientation.

The thickness of the base member 25 is set to be slightly larger than, for example, the length of the electronic components 27 or the length of the metal objects 28.

Since each of the dimensions of the through-holes 26 is set to be slightly smaller than a corresponding dimension of the width and thickness of the electronic components 27 or a corresponding dimension of the width and thickness of the metal objects 28, the electronic components 27 or the metal objects 28 are press-fitted into the through-holes 26 with the electronic components 27 or the metal objects 28 stretching the through-holes 26 using elastic deformation of the base member 25.

As a result, the electronic components 27 and the metal objects 28 are reliably held in the through-holes 26 using elastic deformation of the base member 25. Note that, when the electronic components 27 and the metal objects 28 are inserted, the base member 25 may be softened.

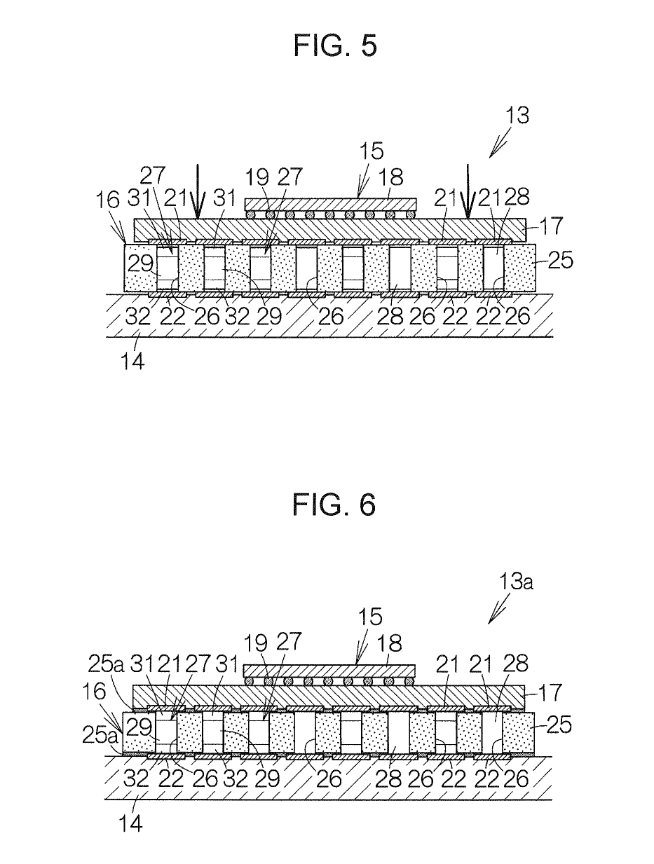

As described FIG. 5, the rear surface of the connection member 16 is disposed on the printed wiring board 14. On the front surface of the connection member 16, the LSI chip package 15 is disposed. The through-holes 26 in which the electronic components 27 are held are positioned for the specified terminal pads 21 and 22.

In this case, the LSI chip package 15 is pressed against the printed wiring board 14. Simultaneously, the connection member 16 is heated. The base member 25 is softened by being heated. The base member 25 is pressed and spread out between the printed wiring board 14 and the package substrate 17 by the LSI chip package 15 being pressed. In this manner, the electrodes 31 and 32 of the electronic components 27 or the upper and lower ends of the metal objects 28 come into contact with the terminal pads 21 and 22.

The connection member 16 is cooled to a room temperature. The base member 25 is solidified by being cooled. As a result, the front surface of the base member 25 is fused to the rear surface of the package substrate 17. The rear surface of the base member 25 is fused to the front surface of the printed wiring board 14.

In this manner, the front and rear surfaces of the base member 25 are attached to the rear surface of the package substrate 17 and the front surface of the printed wiring board 14, respectively. As a result, the base member 25 is mechanically fixed on the package substrate 17 and the printed wiring board 14.

Simultaneously, the electrodes 31 and 32 of the electronic components 27 or the upper and lower ends of the metal objects 28 are in contact with the terminal pads 21 and 22. As a result, the electronic components 27 and the metal objects 28 are electrically connected to the terminal pads 21 and 22. With a function of the base member 25, the LSI chip package 15 is implemented on the front surface of the printed wiring board 14. In this manner, the printed circuit board unit 13 is produced.

Furthermore, a mold may be prepared for production of the connection member 16. In the mold, the electronic components 27 or the metal objects 28 are disposed at specific positions in advance. A fluid resin material is poured into the mold. For example, a thermosetting resin material may be used as the resin material.

The half-cured base member 25 is formed in the mold in accordance with adjustment of a heating temperature. The through-holes 26 are formed in the base member 25 based on the electronic components 27 or the metal objects 28. In this manner, the positions of the electronic components 27 or the metal objects 28 are temporarily determined.

The half-cured connection member 16 is heated between the printed wiring board 14 and the package substrate 17. The half-cured base member 25 is pressed against the printed wiring board 14 because of the weight of the package substrate 17. As a result, the base member 25 is cured while being fused to the printed wiring board 14 and the package substrate 17.

The electronic components 27 or the metal objects 28 are connected to the terminal pads 21 and 22.

FIG. 6 schematically illustrates a structure of a printed circuit board unit 13a according to a second embodiment of the present invention. In the printed circuit board unit 13a, adhesive layers 25a are sandwiched between the rear surface of the package substrate 17 and the front surface of the base member 25 or between the rear surface of the base member 25 and the front surface of the printed wiring board 14. The adhesive layers 25a extend over the front or rear surface of the base member 25 around the through-holes 26.

However, the adhesive layers 25a may extend onto portions of the front or rear surface of the base member 25. With the adhesive layers 25a, the base member 25 is attached to the rear surface of the package substrate 17 or the front surface of the printed wiring board 14. In formation of the adhesive layers 25a, when the connection member 16 is produced, an adhesive may be applied onto the front or rear surface of the base member 25 in advance or an adhesive sheet may be attached to the front or rear surface of the base member 25 in advance.

Further, elements having configurations or structures that are equivalent to the configurations or structures of elements of the above-described printed circuit board unit 13 are designated by the same reference numerals.

In the printed circuit board unit 13a structured as described above, the base member 25 is attached to the rear surface of the package substrate 17 or the front surface of the printed wiring board 14 with the adhesive layers 25a. Accordingly, it is not necessary to heat the base member 25 in production of the printed circuit board unit 13a.

Furthermore, in production of the printed circuit board unit 13a, light pressing of the LSI chip package 15 against the printed wiring board 14 is sufficient to achieve adhesion of the adhesive layers 25a.

As a result, the LSI chip package 15, the printed wiring board 14, and the electronic components 27 may not be subjected to extreme heat stress or mechanical stress. Additionally, with the printed circuit board unit 13a structured as described above, advantages which are similar to those of the above-described printed circuit board unit 13 are realized.

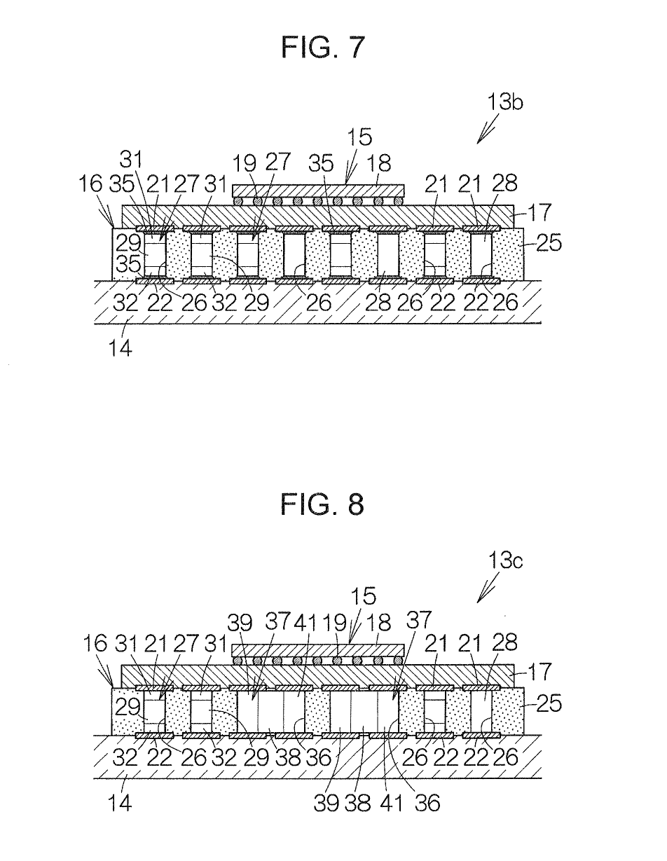

FIG. 7 schematically illustrates a structure of a printed circuit board unit 13b according to a third embodiment of the present invention. In the printed circuit board unit 13b, solder members 35 are sandwiched between the electrodes 31 and 32 of the electronic components 27 or the metal objects 28 and the terminal pads 21 and 22.

With a function of the solder members 35, the electrodes 31 and 32 or the metal objects 28 are reliably electrically and mechanically joined to the terminal pads 21 and 22. Instead of the solder members 35, conductive adhesive members may be sandwiched between the electrodes 31 and 32 of the electronic components 27 or the metal objects 28 and the terminal pads 21 and 22.

Furthermore, elements having configurations or structures that are equivalent to the configurations or structures of the elements of any one of the above-described printed circuit board units 13 and 13a are designated by the same reference numerals.

When production of the printed circuit board unit 13b structured as described above is performed, the solder members 35 are heated, for example, for melting of the solder members 35. The base member 25 is softened when the solder members 35 are heated. As a result, the base member 25 is fused to the package substrate 17 and the printed wiring board 14 when the electrodes 31 and 32 of the electronic components 27 or the metal objects 28 are joined to the terminal pads 21 and 22.

Further, when, for example, a eutectic solder, such as a tin-lead alloy, or a high-temperature solder, such as a tin-silver-copper alloy, is used for the solder members 35, the solder members 35 may be heated when electronic components are soldered as peripheral circuit components outside the contour of the LSI chip package 15 on the front or rear surface of the printed wiring board 14. Note that, when the melting point of the solder members 35 is different from a temperature at which the base member 25 is softened, application of heat to the solder members 35 and application of heat to the base member 25 may be performed as different processes.

The solder members 35 or the adhesive members may be applied onto the electrodes 31 and 32 or onto the metal objects 28 in advance when production of the connection member 16 is performed. Alternatively, the solder members 35 or the adhesive members may be applied onto the electrodes 31 and 32 or onto the metal objects 28 when production of the printed circuit board unit 13b is performed. With the printed circuit board unit 13b structured as described above, advantages that are similar to the above-described advantages are realized.

FIG. 8 schematically illustrates a structure of a printed circuit board unit 13c according to a fourth embodiment of the present invention. In the printed circuit board unit 13c, particular through-holes 36 are formed so that the particular through-holes 36 correspond to the terminal pads 21 or 22 and a ratio of the number of through-holes 36 to the number of terminal pads 21 or 22 is a ratio of one to two. A through-hole 36 is formed to span across terminal pads 21 adjacent to each other and terminal pads 22 adjacent to each other. Accordingly, the dimensions of the through-holes 36 are larger than the dimensions of the through-holes 26.

Electronic components 37, such as bypass capacitors, are disposed in the through-holes 36. Each of the electronic components 37 includes a chip body 38. The chip body 38 includes a base member that is formed of, for example, a ceramic material. In the base member, for example, internal electrodes are disposed. Electrodes 39 and 40 are provided at the ends of the chip body 38. Ends of each of the electrodes 39 and 41 are exposed at the front and rear surfaces of the base member 25.

The thickness of the electronic components 37 is set to be substantially equal to the length of the electronic components 27 or the length of the metal object 28, e.g., to be 1.0 mm. As a result, the length of the electrode 39 and the length of the electrode 41 coincides with the length of the electronic components 27 or the metal objects 28. The electrodes 39 and 41 may be formed of, for example, copper. On the surface of the copper, for example, a tin plating film or a nickel plating film may be formed.

One end of the electrode 39 receives one of the terminal pads 21. The other end of the electrode 39 is received by one of the terminal pads 22. Similarly, one end of the electrode 41 receives the other terminal pad 21. The other end of the electrode 41 is received by the other terminal pad 22.

In this manner, the individual electrodes 39 and 41 directly connect the terminal pads 21 to the corresponding terminal pads 22. Here, the terminal pad 21 that is connected to the electrode 39 is configured as a power-supply terminal. The terminal pad 21 that is connected to the electrode 41 is configured as a ground terminal.

In this manner, feeding is performed by connecting the terminal pads 21 to the corresponding terminal pads 22. Furthermore, elements having configurations or structures that are equivalent to the configurations or structures of the elements of any one of the above-described printed circuit board units 13 to 13b are designated by the same reference numerals.

With the printed circuit board unit 13c structured as described above, advantages that are similar to the above-described advantages are realized. Note that the adhesive layers 25a, the solder members 35, or the conductive adhesive members, which are described above, may also be incorporated into the printed circuit board unit 13c.

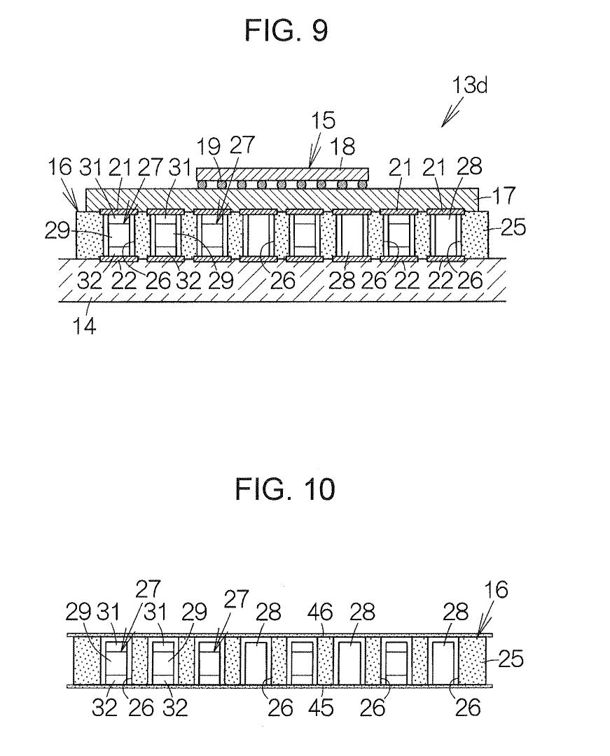

FIG. 9 schematically illustrates a structure of a printed circuit board unit 13d according to a fifth embodiment of the present invention. In the printed circuit board unit 13d, each of the dimensions of the through-holes 26 of the base member 25 is set to be larger than a corresponding dimension of the width and thickness of the electronic components 27 or a corresponding dimension of the width and thickness of the metal objects 28.

As a result, clearances are formed between the electronic components 27 or the metal objects 28 and the inner walls of the through-holes 26. However, preferably, each of the dimensions of the through-holes 26 is set to be smaller than a radius of the surfaces of the terminal pads 21 and 22. As a result, the opening portions of the through-holes 26 are reliably disposed inside the terminal pads 21 and 22.

The electrodes 31 and 32 or the upper and lower ends of the metal object 28 are reliably connected to the terminal pads 21 and 22. Furthermore, elements having configurations or structures that are equivalent to the configurations or structures of the elements of any one of the above-described printed circuit board units 13 to 13c are designated by the same reference numerals.

Next, a method for producing the printed circuit board unit 13d will be described. First, the connection member 16 is produced. As described above, the base material 25 is molded. As illustrated in FIG. 10, a detachment-prevention film 45 that is made of, for example, a resin is attached to the rear surface of the base member 25.

The electronic components 27 or the metal objects 28 are disposed in the through-holes 26 so that the electronic components 27 or the metal object 28 are oriented vertically. The thickness of the base member 25 is set to be slightly larger than the length of the electronic components 27 or the length of the metal objects 28. After that, a detachment-prevention film 46 that is made of, for example, a resin is attached to the front surface of the base member 25.

In this manner, a connection member unit is formed. In the connection member unit, with functions of the detachment-prevention films 45 and 46, the electronic components 27 or the metal object 28 are prevented from detaching from the through-holes 26.

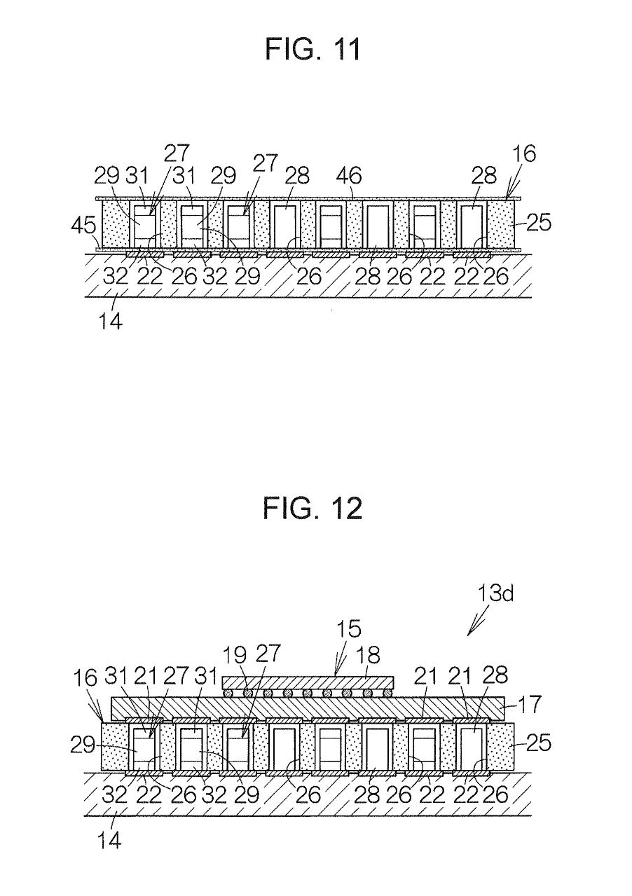

As illustrated in FIG. 11, the connection member unit is disposed on the printed wiring board 14. Regarding the positions of the through-holes 26, the through-holes 26 are positioned on the terminal pads 22. In this case, the detachment-prevention film 45 is removed from between the base member 25 and the printed wiring board 14.

As a result, the electronic components 27 or the metal objects 28 in the through-holes 26 are received by the terminal pads 22. The detachment-prevention film 46 is removed from the front surface of the base member 25. As illustrated in FIG. 12, the LSI chip package 15 is disposed on the front surface of the base member 25. Regarding the positions of the terminal pads 21, the terminal pads 21 are positioned on the through-holes 26.

As described above, the LSI chip package 15 is pressed against the printed wiring board 14. Simultaneously, the connection member 16 is heated. The base member 25 is pressed and spread out between the printed wiring board 14 and the package substrate 17 by the LSI chip package 15 being pressed.

In this manner, the electrodes 31 and 32 of the electronic components 27 or the upper and lower ends of the metal objects 28 are in contact with the terminal pads 21 and 22. After that, because the base member 25 is solidified, the front and rear surfaces of the base member 25 are fused to the package substrate 17 and the printed wiring board 14, respectively. The electrodes 31 and 32 of the electronic components 27 or the upper and lower ends of the metal objects 28 are in contact with the terminal pads 21 and 22.

With the printed circuit board unit 13d structured as described above, advantages that are similar to the above-described advantages are realized. Additionally, clearances are formed between the electronic components 27 and the inner walls of the through-holes 26.

Accordingly, in production of the connection member 16, the electronic components 27 do not need to be pressed into the through-holes 26. Thus, the electronic components 27 may not suffer from mechanical stress. Damage to the electronic components 27 is reliably reduced if not prevented.

However, as in the above-described case, preferably, the solder members 35 or the conductive adhesive members are sandwiched between the electrodes 31 and 32 of the electronic components 27 or the upper and lower ends of the metal objects 28 and the terminal pads 21 and 22. With the solder members 35 or the adhesive members, which are given above, the electronic components 27 and the metal objects 28 are reliably electrically joined to the terminal pads 21 and 22.

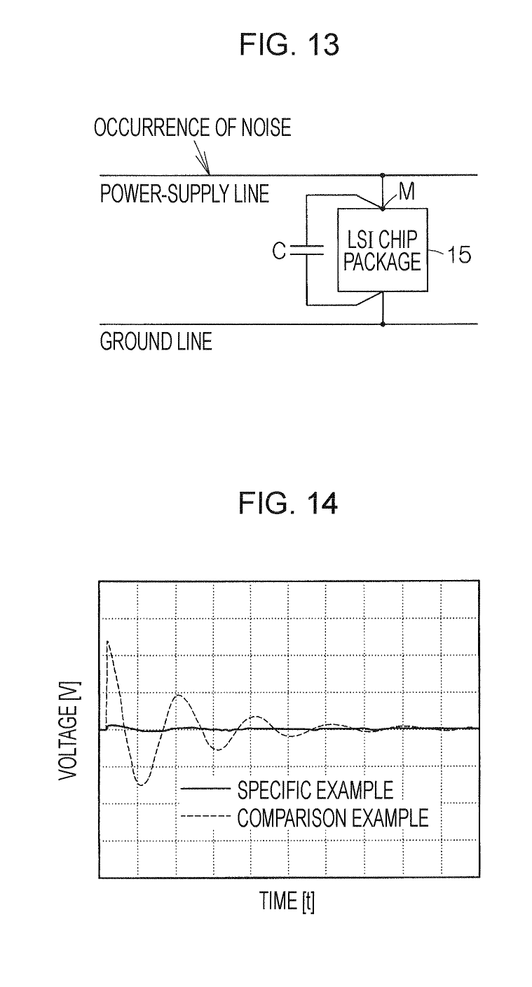

The inventor performed verification of the advantages of the present invention using simulation. For the verification, a specific example according to the present embodiments and a comparison example according to the related art were assumed. FIG. 13 is a circuit diagram corresponding to the specific example and the comparison example. In the specific example, an electronic component 27, here, a bypass capacitor C, was disposed between the LSI chip package 15 and the printed wiring board 14.

In the comparison example, the bypass capacitor C was disposed on the rear surface of the printed wiring board 14. The bypass capacitor was connected, via a through-hole that was formed in the printed wiring board 14, to a corresponding terminal pad 22 on the front surface of the printed wiring board 14. The corresponding terminal pads 21 and 22 were connected to each other, for example, using a solder member.

Assuming occurrence of noise that is caused by, for example, a variation in the voltage of a power-supply line, a voltage value was measured at a measurement point M on the circuit. As a result, as illustrated in FIG. 14, in the comparison example, the variation in the voltage was not sufficiently reduced.

In contrast, in the specific example, very little variation in the voltage was observed. The variation in the voltage in the specific example is reduced to be a voltage that is approximately 1/20th of the variation in the voltage in the comparison example. It was verified that noise was markedly reduced in the specific example.

According to the present invention, it was verified that the inductance L is markedly reduced because the electronic components 27 including the bypass capacitor are disposed between the LSI chip package 15 and the printed wiring board 14.

According to the above-described embodiments, for example, the server computer apparatus 11 may be applicable as the electronic equipment. However, any of the connection member 16 and the printed circuit board units 13 to 13d according to the present invention may be incorporated into compact electronic equipment, such as a mobile phone, or other electronic equipment.

Examples of embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made therein without departing from the spirit and scope of the present invention as set forth in the claims.

What is claimed is:

1. A connection member disposed between a semiconductor package and a printed wiring board, the connection member comprising:
a base member formed of an insulating material;
a plurality of through-holes provided in the base member at corresponding positions between a plurality of first terminal pads of the semiconductor package and a plurality of second terminal pads of the printed wiring board; and
an electronic component inserted in the plurality of through-holes, the electronic component having a first electrode and a second electrode at ends thereof, the first electrode connected to one of the first terminal pads, the second electrode connected to one of the second terminal pads.

2. The connection member according to claim 1, wherein the electronic component is at least any one of a resistor, a capacitor, an inductor, and a fuse element.

3. The connection member according to claim 1, further comprising a metal object inserted in the plurality of through-holes.

4. The connection member according to claim 1, wherein at least one of the through-holes has a size corresponding to the plurality of the first terminal pads and the plurality of the second terminal pads.

5. The connection member according to claim 4, wherein a bypass capacitor is inserted in the at least one of the through-holes having a size corresponding to the plurality of the first terminal pads and the plurality of the second terminal pads.

6. The connection member according to claim 4, wherein the first terminal pads include a power-supply terminal pad and a ground terminal pad.

7. A printed circuit board unit comprising:
a semiconductor package provided with first terminal pads;
a printed wiring board provided with second terminal pads, the printed wiring board facing the package substrate; and
a connection member disposed between the semiconductor package and the printed wiring board,
wherein the connection member includes:
a base member formed of an insulating material;
a plurality of through-holes provided in the base member at corresponding positions between first terminal pads of the semiconductor package and second terminal pads of the printed wiring board; and
an electronic component inserted in the through-holes, the electronic component having a first electrode and a second electrode at ends thereof, the first electrode connected to one of the first terminal pads, the second electrode connected to one of the second terminal pads.
